(19) United States
(12) Patent Application Publication
(10) Pub. No.: US 2025/0076052 A1
(43) Pub. Date: Mar. 6, 2025

(54) Circuit Device And Circuit Device Setting Method

(71) Applicant: SEIKO EPSON CORPORATION, Tokyo (JP)

(72) Inventors: Kiminori NAKAJIMA, Shiojiri (JP); Tomoaki TAKAHASHI, Minowa (JP)

(21) Appl. No.: 18/817,299

(22) Filed: Aug. 28, 2024

(30) Foreign Application Priority Data
Aug. 29, 2023 (JP) 2023-138528

(51) Int. Cl. G01C 19/5776; H03H 17/02; H03H 17/04

(52) U.S. Cl. CPC G01C 19/5776; H03H 17/025; H03H 17/0294; H03H 2017/0298; H03H 17/04

(57) ABSTRACT

A circuit device includes an A/D conversion circuit that A/D converts a signal output from a sensor element, an interface circuit that receives filter setting data that determines a characteristic of each of a plurality of digital filtering processes, a storage circuit that stores the filter setting data, and a signal processing circuit that sequentially performs each of the plurality of digital filtering processes with characteristics determined by the filter setting data on a digital signal output from the A/D conversion circuit.

The present application is based on, and claims priority from JP Application Serial Number 2023-138528, filed Aug. 29, 2023, the disclosure of which is hereby incorporated by reference herein in its entirety.

### BACKGROUND

### 1. Technical Field

The present disclosure relates to a circuit device and a method of setting the circuit device.

In the related art, a technique is known to convert an analog signal output from a sensor element into a digital signal and perform a digital filtering process. For example, JP-A-2015-108566 discloses a configuration in which a band elimination filter attenuates a component of the detuned frequency Δf corresponding to the difference between the drive side resonance frequency fd and the detection side resonance frequency fs of the resonator.

In the related art, it has not been possible to set a filter characteristic to the user's desired filter characteristic according to the user's application.

### SUMMARY

According to an aspect of the present disclosure, a circuit device includes an A/D conversion circuit that A/D converts a signal output from a sensor element, an interface circuit that receives filter setting data that determines a characteristic of each of a plurality of digital filtering processes, a storage circuit that stores the filter setting data, and a signal processing circuit that sequentially performs each of the plurality of digital filtering processes with characteristics determined by the filter setting data on a digital signal output from the A/D conversion circuit.

According to another aspect of the present disclosure, in a method of setting a circuit device including an A/D conversion circuit that A/D converts a signal output from a sensor element, an interface circuit, a storage circuit, and a signal processing circuit that performs a digital filtering process on a digital signal output from the A/D conversion circuit, the method includes inputting filter setting data that determines a characteristic of each of a plurality of digital filtering processes into the interface circuit, and storing the filter setting data in the storage circuit, and causing the signal processing circuit to sequentially perform each of the plurality of digital filtering processes with characteristics determined by the filter setting data on the digital signal output from the A/D conversion circuit.

### BRIEF DESCRIPTION OF THE DRAWINGS

FIG. 1 is a functional block diagram of a physical quantity sensor according to the first embodiment.

FIG. 2 is an example of filter characteristics.

FIG. 3 is a block diagram of a DSP.

FIG. 4 is a configuration example of a programmable filter.

FIG. 5 is a configuration example of a second-order IIR filter.

FIG. 6 is a flowchart of the setting process.

### DESCRIPTION OF EMBODIMENTS

Hereinafter, preferred embodiments of the present disclosure will be described in detail with reference to the drawings. The embodiments described below do not unduly limit the details of the present disclosure described in the claims. In addition, all of the configurations described below are not necessarily essential components of the present disclosure. In the following, description of a physical quantity sensor (angular velocity sensor) that detects an angular velocity as a physical quantity is made as an example.

### 1. First Embodiment

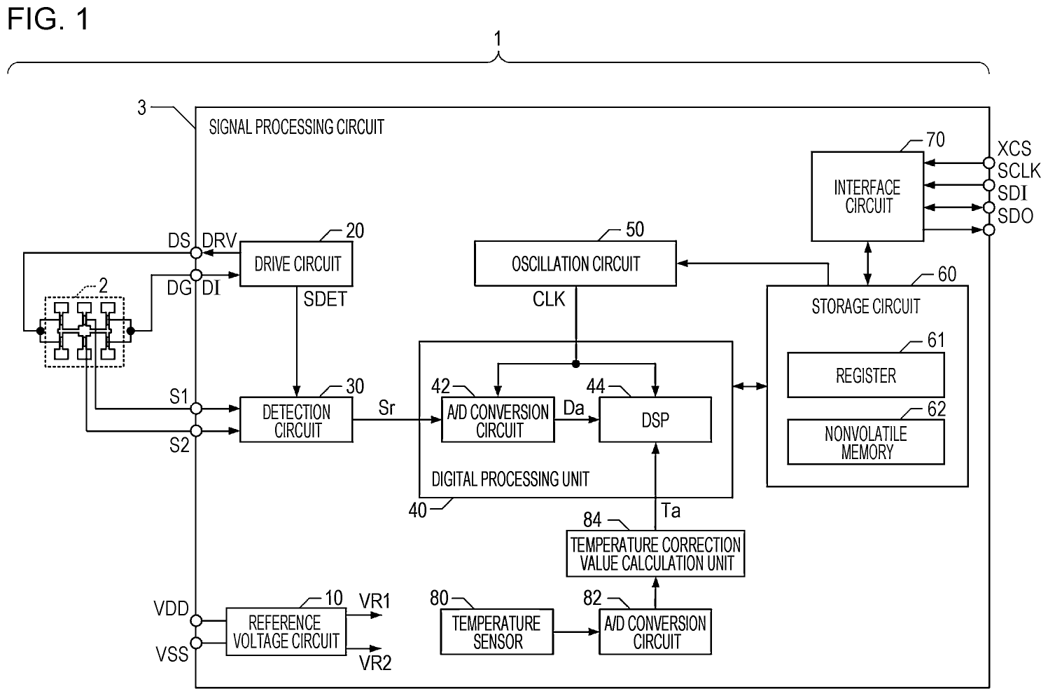

FIG. 1 is a functional block diagram of a physical quantity sensor according to the first embodiment. A physical quantity sensor 1 of the first embodiment includes a sensor element 2 and a circuit device 3. In the present embodiment, the sensor element 2 is an angular velocity sensor. The angular velocity sensors can be achieved by various known configurations. For example, the sensor element 2 can be configured by an element or the like that outputs a signal indicating vibration based on the Coriolis force acting on the vibrating arm. Of course, the shape of the sensor is not limited, and a variety of sensor shapes can be used, including a double-T type, a tuning fork type, and an H-type.

The sensor element 2 includes an input terminal to which a drive signal DRV is input from a drive circuit 20 and an output terminal from which a feedback signal DI is output to the drive circuit 20. In the present embodiment, the input terminal is electrically coupled to a pad DS. The output terminal is electrically coupled to a pad DG. The sensor element 2 includes two detection signal output terminals that output detection signals, and respective detection signal output terminal are electrically coupled to pads S1 and S2.

The circuit device 3 in the present embodiment includes a reference voltage circuit 10, the drive circuit 20, a detection circuit 30, a digital processing unit 40, an oscillation circuit 50, a storage unit 60, an interface circuit 70, a temperature sensor 80, an A/D conversion circuit 82, and a temperature correction value calculation unit 84. The circuit device 3 may be, for example, a single-chip integrated circuit (IC). The circuit device 3 may be configured by omitting or changing some of these elements or adding another element.

The reference voltage circuit 10 generates constant voltages such as reference voltages VR1 and VR2 and constant currents from the supply voltage supplied from a VDD terminal of the circuit device 3, and supplies them to the drive circuit 20 and the detection circuit 30.

The drive circuit 20 drives the sensor element 2. The drive circuit 20 is electrically coupled to the sensor element 2 via the pads DS and DG. The drive circuit 20 receives the feedback signal DI from the sensor element 2 via the pad DG to output the drive signal DRV corresponding to the feedback signal DI via the pad DS to thereby drive the sensor element 2. The drive circuit 20 generates a detection signal SDET that has the same phase as the drive signal DRV to output the detection signal SDET to the detection circuit 30.

The drive circuit 20 can be achieved by various known circuits. For example, the drive circuit 20 can be achieved by a configuration including a current-to-voltage converter (I/V converter), a gain control circuit, and two comparators. That is, the AC voltage signals output from the current-to-voltage converter are converted by the respective comparators to the drive signal DRV and the detection signal SDET. The gain control circuit controls the reference voltage of the comparator so that the amplitude of the AC voltage signal input to the comparator that generates the drive signal DRV is held at a constant value. The frequency of the drive signal DRV is referred to here as a drive frequency fd.

The detection circuit 30 detects the angular velocity component in the AC charge input from the sensor element 2 via the S1 and S2 terminals to output a detection signal Sr, which is an analog signal with a voltage level corresponding to the magnitude of the angular velocity. In the present embodiment, the frequency of the AC charge input from the sensor element 2 via the S1 and S2 terminals is referred to as a detection frequency fr. The detection circuit 30 can be achieved by various known circuits. For example, the detection circuit 30 can be achieved by a configuration including a QV amplifier, a differential amplifier, a variable gain amplifier (programmable gain amplifier (PGA)), a synchronous detection circuit and a low-pass filter. The synchronous detection circuit synchronously detects the angular velocity component in the signal output from the variable gain amplifier using the detection signal SDET.

The storage unit 60 includes a register 61 and a nonvolatile memory 62. The register 61 stores addresses and various pieces of data used in communication with an external device via the interface circuit 70. In the present embodiment, the various types of data include filter setting data. In other words, the interface circuit 70 receives the filter setting data that determines the characteristic of each of the plurality of digital filtering processes (second-order infinite impulse response (IIR) filters described below). The received filter setting data is stored in the register 61. The register 61 stores angular velocity data and angle data output from a DSP 44, which will be described later.

The nonvolatile memory 62 stores various pieces of adjustment data and correction data for the drive circuit 20 and the detection circuit 30, as well as various pieces of information for establishing communication with the outside world via the interface circuit 70. The nonvolatile memory 62 can be configured, for example, as a metal oxide nitride silicon (MONOS) type memory or an electrically erasable programmable read-only memory (EEPROM).

The interface circuit 70 is electrically coupled to an XCS terminal, an SCLK terminal, an SDI terminal, and an SDO terminal and is used to communicate with an external device via these terminals. In communication via the interface circuit 70, the external device functions as a master and the physical quantity sensor 1 (circuit device 3) functions as a slave. The external device can then write data to a predetermined address of the register 61, read data from a predetermined address of the register 61, and transmit various commands to control the operation of the circuit device 3 via the interface circuit 70.

The interface circuit 70 may function as either one of a serial peripheral interface (SPI) circuit or a I2C (inter-integrated circuit) interface circuit. For example, when an XCS terminal is at low level, the interface circuit 70 functions as the SPI circuit, a clock signal is input via the SCLK terminal, a data signal is input via the SDI terminal, and a data signal is output via the SDO terminal. When the XCS terminal is at high, the interface circuit 70 functions as the I2C interface circuit, a clock signal is input via the SCLK terminal, and a data signal is input and output via the SDI terminal.

Communication with an external device via the interface circuit 70 is based on various pieces of information stored in the register 61. The external device can then read the angular velocity data from a predetermined address in the register 61 via the interface circuit 70. Thus, the physical quantity sensor 1 (circuit device 3) is configured to output angular velocity data upon request from the external device.

In the present embodiment, the frequency of a clock signal CLK is determined according to the natural frequency of the sensor element 2 when the physical quantity sensor 1 is manufactured, and a sampling frequency fs in the A/D conversion described below is determined according to the frequency of the clock signal CLK. Specifically, at the time of factory shipment or the like, as in the related art described above, when the drive frequency of the drive signal used to drive the sensor element 2 is fd as described above, and the frequency of the clock signal CLK is fck, j×fd≠fck/i where i and j are integers of one or more. Once the frequency fck of the clock signal is determined, the frequency same as the frequency fck of the clock signal or the frequency multiplied by the frequency of the clock signal CLK is the sampling frequency fs. The frequency of the clock signal CLK and sampling frequency fs are stored in the nonvolatile memory 62, and the sampling frequency fs is stored at a predetermined address in the register 61. The user can read the sampling frequency fs stored at the address using an external device. Here, the storage area in the register 61 where the sampling frequency fs is stored is referred to as a first area.

Furthermore, in the present embodiment, the digital filtering process is performed by the DSP 44, which is described below. In the present embodiment, the digital filtering process includes a programmable filter 44b, a selectable filter 44c, and a notch filter 44d, which are described below. The programmable filter 44b is a filter that can be set to be a filter with any characteristic by the user setting the filter coefficient using filter setting data, details of which are described below.

The selectable filter 44c is a filter that allows the user to select a desired characteristic from a predetermined number of characteristics. The nonvolatile memory 62 stores the filter coefficient associated with each setting. The number of filter characteristics and selectable characteristics is arbitrary, but an example is assumed in which the characteristic of the low-pass filtering process can be selected from 24 characteristics.

Specifically, the selectable filter 44c is composed of a plurality of orders of IIR filters and the like, and the filter coefficient corresponding to each of the combinations of an order n and a cutoff frequency fc (each of 24 combinations) is predetermined and stored in the nonvolatile memory 62. The filter coefficient is a value used to set the low-pass filtering process for the order n and the cutoff frequency fc with which the filter coefficient is associated.

In the present embodiment, the characteristic of the low-pass filtering process achieved by the combination of the order n and the cutoff frequency fc is shown to the user in advance by a manual and the like. Therefore, the user can grasp the characteristic of the selectable low-pass filtering process by referring to the manual and the like.

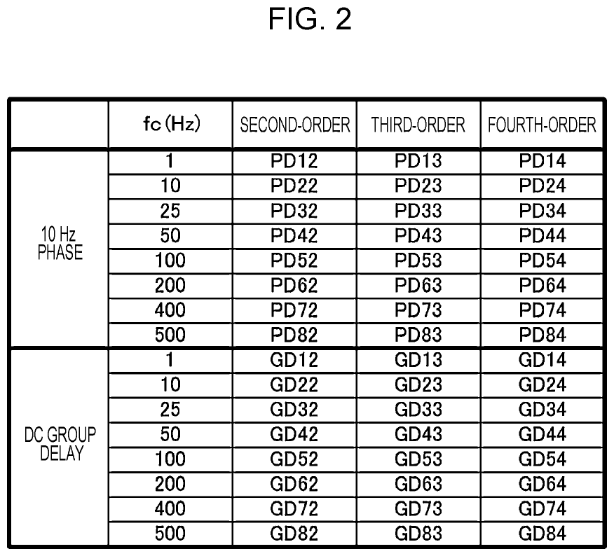

FIG. 2 shows an example of filter characteristics. In the present embodiment, three different orders (second-order to fourth-order) and eight different cutoff frequencies fc are selectable, so that a total of 24 different characteristics are selectable. In FIG. 2, an example is shown in which the phase delay characteristics when the input signal is 10 Hz and the group delay characteristics when the input signal is a DC signal are associated with each other in respective combinations. For example, for a low-pass filtering process with the order being two and the cutoff frequency fc being 1 Hz, the phase delay characteristic is PD12 (deg) and the group delay characteristic is GD12 (ms).

The user selects the desired characteristic from the characteristics of the low-pass filtering process, operates an external device, and designates the order n and the cutoff frequency fc. Since the filter coefficient is associated with the order n and the cutoff frequency fc in the nonvolatile memory 62, the characteristic of the selectable filter 44c can be selected so that the low-pass filtering process of the characteristics designated by the user is perform by operating the selectable filter 44c using the filter coefficient. The detailed process by the selectable filter 44c is described below.

The notch filter 44d is a band elimination filter for attenuating a signal at a specific frequency. In the present embodiment, the notch filter 44d is a filter that attenuates the component of the detuned frequency that is the difference between the drive frequency fd and the detection frequency fr. The notch filter 44d can be achieved by, for example, an IIR filter. The nonvolatile memory 62 stores information indicating the filter coefficients that should be applied to the notch filter 44d to attenuate the components of that detuned frequency. The information indicating the filter coefficients is transferred to the register 61 when the physical quantity sensor 1 is activated, and is referenced to by the DSP 44 described below.

The oscillation circuit 50 generates the clock signal CLK to output the clock signal CLK to the digital processing unit 40. The oscillation circuit 50 includes a phase locked loop (PLL) circuit and a digital locked loop (DLL) circuit, and outputs the clock signal CLK of a frequency stored in the storage unit 60. In other words, the nonvolatile memory 62 stores the frequency of the clock signal CLK, and when the physical quantity sensor 1 is activated, the frequency is transferred to the register 61. The oscillation circuit 50 acquires the frequency stored in the register 61 and generates an oscillation signal by the frequency to make the clock signal CLK.

The digital processing unit 40 includes an analog to digital (A/D) conversion circuit 42 and a digital signal processor (DSP) 44 as a signal processing circuit. The A/D conversion circuit 42 operates at the sampling frequency fs synchronized with the clock signal CLK output by the oscillation circuit 50 to convert the output signal of the detection circuit 30 into a digital signal (angular velocity data) Da for output. The sampling frequency fs that is a period at which the A/D conversion circuit 42 converts the analog signal to a digital signal may be the same as the frequency of the clock signal CLK, or may be a frequency multiplied by the frequency of the clock signal CLK. The A/D conversion circuit 42 can be achieved with various known circuits, and for example, can be a delta-sigma type or successive comparison type A/D conversion circuit.

The DSP 44 operates in synchronization with the clock signal CLK output by the oscillation circuit 50 and performs a digital process including the digital filtering process on the digital signal (angular velocity data) Da output from the A/D conversion circuit 42. The configuration of the DSP 44 is described below. The digital process includes, in addition to the digital filtering process, a digital process of correcting temperature-dependent variations in angular velocity data. These digitally processed angular velocity data value represents the angular velocity detected by the sensor element 2 and is updated sequentially at a predetermined rate. In addition, the DSP 44 may perform a digital process of correcting the offset of the zero point of the angular velocity data or a digital process of calculating the angular velocity data by integrating (adding) the sequentially updated angular velocity data over time. The angular velocity data output from the DPS44 is stored in the register 61 and transferred to an external device or the like, for example, via the interface circuit 70.

The temperature sensor 80 is a sensor that outputs a voltage level signal (temperature signal) in accordance with the temperature of its surroundings, and may be a positive polarity in which the higher the temperature, the higher the output voltage, or a negative polarity in which the higher the temperature, the lower the output voltage. The temperature sensor 80 may be, for example, a circuit that outputs a voltage proportional to the absolute temperature (proportional to absolute temperature (PTAT) voltage). The temperature signal output from the temperature sensor 80 is input to the A/D conversion circuit 82.

The A/D conversion circuit 82 operates in synchronization with the clock signal CLK output by the oscillation circuit 50 to convert the signal output by the temperature sensor 80 into a digital signal (temperature data) for output. The sampling frequency fs that is a period at which the A/D conversion circuit 82 converts the analog signal to a digital signal may be the same as the frequency of the clock signal CLK, or may be a frequency multiplied by the clock signal CLK. The A/D conversion circuit 82 can be achieved with various known circuits, and for example, can be a delta-sigma type or successive comparison type A/D conversion circuit. The signal output from the A/D conversion circuit 82 is input to the temperature correction value calculation unit 84.

The temperature correction value calculation unit 84 calculates and outputs a temperature correction value Ta based on the signal output by the A/D conversion circuit 82. The method of calculating the temperature correction value Ta may be various methods, and may, for example, include a method of calculating the temperature correction value Ta using a function with the temperature as a variable, or a method of acquiring the temperature correction value Ta corresponding to the temperature based on information stored in the storage unit 60. The temperature correction value Ta output from the temperature correction value calculation unit 84 is input to the DSP 44. The temperature correction value calculation unit 84 is only required to be a circuit that performs a digital process, and may be achieved by various integrated circuits such as a CPU, or may be achieved by a field programmable gate array (FPGA), for example.

### 1.1 DSP Configuration

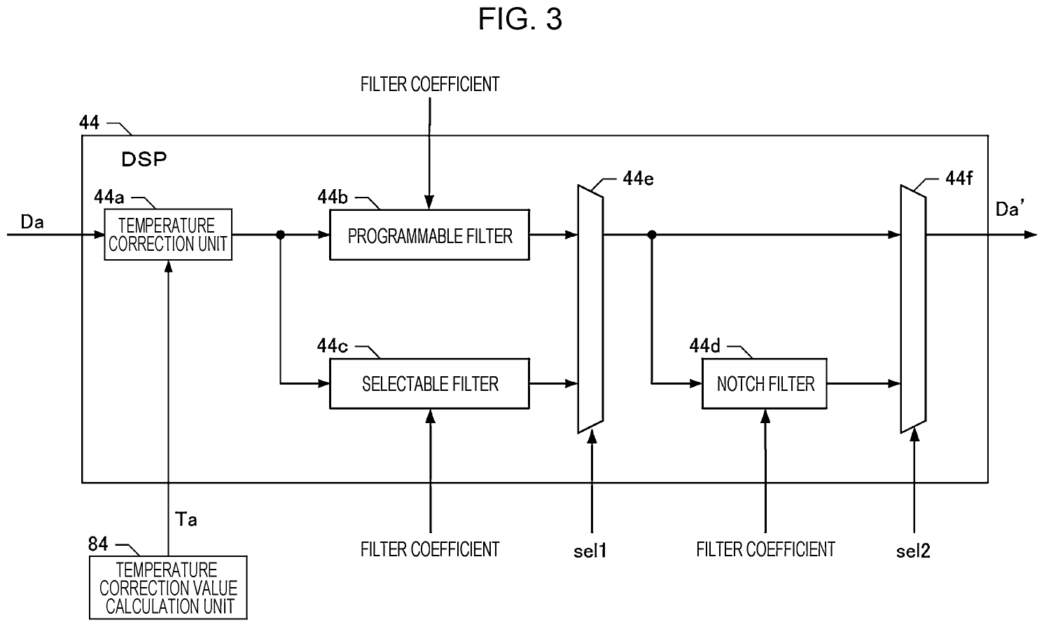

The configuration of the DSP 44 is described in detail next. FIG. 3 shows a block diagram of the DSP 44. The DSP 44 includes a temperature correction unit 44a, the programmable filter 44b, the selectable filter 44c, the notch filter 44d, selectors 44e and 44f. The temperature correction unit 44a corrects a digital signal Da based on the temperature correction value Ta output by the temperature correction value calculation unit 84. The temperature correction value Ta is a value for cancelling out fluctuations in the output of the sensor element 2 due to temperature, and in the present embodiment, the temperature correction unit 44a corrects the digital signal Da by performing a predetermined operation based on the temperature correction value Ta, for example, Da+Ta, on the digital signal Da.

The programmable filter 44b is a filter that can be set to be a filter with any desired characteristic by the user setting the filter coefficient with the filter setting data. The programmable filter 44b can be achieved by various configurations, and in the present embodiment, is achieved by four second-order IIR filters coupled in series.

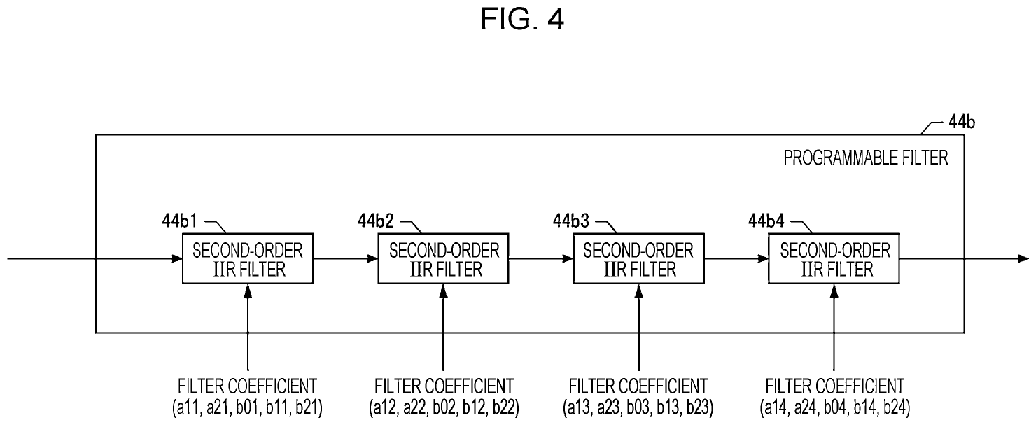

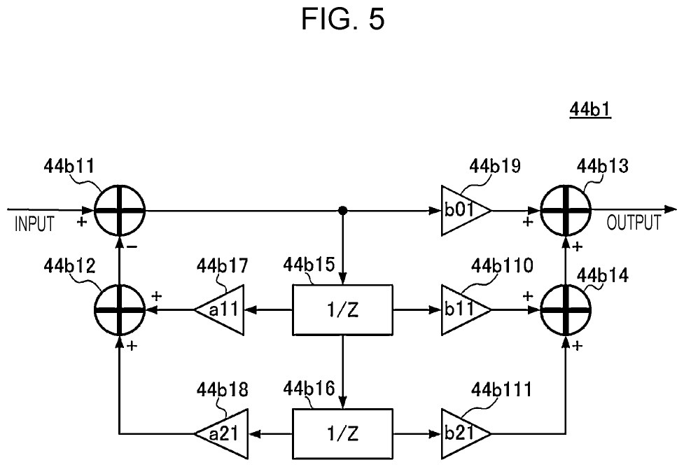

FIG. 4 illustrates the configuration of the programmable filter 44b. The programmable filter 44b includes second-order IIR filters 44b1, 44b2, 44b3, and 44b4 coupled in series in this order. The second-order IIR filters 44b1, 44b2, 44b3, and 44b4 have similar configurations, and the configuration of the second-order IIR filter 44b1 is shown in FIG. 5.

The second-order IIR filter 44b1 includes adders 44b11 to 44b14, delayers 44b15 and 44b16, and multipliers 44b17 to 44b111. The delayers 44B15 and 44B16 provide unit delay to input signals to output the input signals. The multipliers 44b17 to 44b111 multiply input signals by coefficients to output the input signals. The coefficients of the multipliers 44b17 to 44b111 are a11, a21, b01, b11, and b21 shown for the multipliers 44b17 to 44b111 in FIG. 5. The adders 44b11 to 44b14 add to input signals shown in FIG. 5 reference numerals shown in the figure to output the input signals.

Thus, in the example shown in FIG. 5, the adder 44b11 adds the input signal to the signal obtained by making the feedback signal into a negative signal to output the summed signal. The signal output from the adder 44B11 is delayed by the delayers 44B15 and 44B16. The signal delayed by the delayer 44b15 is input to the multipliers 44b17 and 44b110, and the delayer 44b16. The signal delayed by the delayer 44b16 is input to the multipliers 44b18 and 44b111.

The signals input to the multipliers 44b17 and 44b18 are multiplied by coefficients a11 and a21, added by the adder 44b12, and then input to the adder 44b11. The signals input to the multipliers 44b110 and 44b111 are multiplied by the filter coefficients b11 and b21, added by the adder 44b14, and then input to the adder 44b13. The signal obtained by multiplying the output of the adder 44b11 by the filter coefficient b01 by the multiplier 44b19 is input to the adder 44b13. The adder 44B13 outputs the sum of both input signals.

The second-order IIR filter 44b1 described above can be made into a filter with various characteristics by adjusting the filter coefficients b01, b11, b21, a11, and a21. In the present embodiment, the user can designate these filter coefficients. In other words, the user operates an external device to transmit filter setting data indicating the filter coefficients to the physical quantity sensor 1. When the interface circuit 70 receives the filter setting data, the filter setting data is stored in the register 61. The second-order IIR filter 44b1 refers to the relevant register 61 and determines the filter coefficients b01, b11, b21, a11, and a21 so that the coefficients are the values indicated by the acquired filter setting data.

The second-order IIR filter 44b1 may be set to perform various digital filtering processes. For example, the filter setting data is defined so as to correspond to any one of the bandpass filtering process, the notch filtering process, the low-pass filtering process, and the high-pass filtering process. The filter setting data may be defined so that the phase delay and the group delay are within a desired range.

The user may determine the filter coefficients using various methods, but in the present embodiment, a simulator is used. Specifically, an external device runs the simulator. In this situation, the user operates an external device to tentatively determine the filter coefficient values, simulates a characteristic of the digital filtering process using the tentatively determined filter coefficients, and displays the characteristic on a display unit or the like. When the displayed results are the desired results, the user decides to use the tentatively determined filter coefficients, and when the displayed results are not the desired result, the user changes the filter coefficients and repeats the simulation.

Simulation may be performed using various techniques, and an example is considered in which the gain characteristic, the phase delay characteristic, and the group delay characteristic are simulated using the transfer function of the second-order IIR filter 44b1, for example. The transfer function of the second-order IIR filter 44b1 can be expressed by the following Expression (1).

$$H 1 ( z ) = \frac{b 01 + b 11 {z}^{- 1} + b 21 {z}^{- 2}}{1 + a 11 {z}^{- 1} + a 21 {z}^{- 2}} \qquad ( 1 )$$

where 1/z is the transfer function of the time delay element (for example, delayer 44b15). As shown in Expression (1), the transfer function is a function of the filter coefficients b01, b11, b21, a11, and a21.

Therefore, as the user changes the filter coefficients b01, b11, b21, a11, and a21, the characteristic of the digital filtering process expressed by the transfer function change, and the characteristic can be visualized using a simulator. By adjusting the filter coefficients as described above, the characteristic of the second-order IIR filter 44b1 can be designated.

The present embodiment is configured such that adjustment is performed so that the characteristic desired by the user is obtained by considering the sampling frequency fs. Specifically, the filter characteristics are determined by the transfer function expressed in Expression (1) above, and 1/z in the transfer function depends on the sampling frequency fs. In other words, even with the same filter coefficients, when the sampling frequency fs is different, the characteristics of the digital filtering process expressed by the transfer function, such as the gain characteristic, the phase delay characteristic, and the group delay characteristic, can change.

Specifically, in the present embodiment, the sampling frequency fs is a value determined by the frequency fck of the clock signal, and the frequency fck of the clock signal is dependent on the drive frequency fd of the drive signal of the sensor element 2. Therefore, the sampling frequency fs is individual data that differs for individual sensor elements 2. The operation may be performed at different sampling frequencies fs when the individual physical quantity sensors 1 are different. Therefore, the sampling frequency fs is a value that cannot be determined by the user.

Since the sampling frequency fs can vary from individual sensor to individual sensor, in the present embodiment, the sampling frequency fs is stored in the first area of the register 61 in the initial state after the physical quantity sensor 1 is activated. Therefore, before starting to simulate the filter coefficients, the user operates an external device to read the sampling frequency fs via the interface circuit 70. When the above simulation is performed, the characteristic of the 1/z part in Expression (1) is determined using the acquired sampling frequency fs. Therefore, according to the present embodiment, the filter coefficients to achieve the characteristic desired by the user can be determined according to the sampling frequency fs that varies from individual sensor to individual sensor. Thus, it is possible to accurately determine the filter coefficients to achieve the characteristic desired by the user.

In the present embodiment, the sampling frequency fs is stored in the first area of the register 61. When the sampling frequency fs is then read, the filter coefficients are determined and transmitted as the filter setting data, the filter setting data is stored in the first area of the register 61. In other words, the sampling frequency fs stored in the register 61 is overwritten by the filter setting data. The amount of information about the sampling frequency fs and the amount of information about the filter setting data may be the same or different. In any case, the filter setting data is written to the first area where the sampling frequency fs was stored, allowing efficient use of the storage area of the register 61.

The configuration of each of the second-order IIR filters 44b2 to 44b4 is similar to that of the second-order IIR filter 44b1. In other words, the user simulates the characteristic expressed by the transfer function of each of the 44b2 to 44b4 second-order IIR filters using an external device to determine the filter coefficients. In FIG. 4, the filter coefficients of the second-order IIR filter 44b2 are shown as b02, b12, b22, a12, and a22, and the filter coefficients of the second-order IIR filter 44b3 are shown as b03, b13, b23, a13, and a23. The filter coefficients of the second-order IIR filter 44b4 are shown as b04, b14, b24, a14, and a24.

The transfer functions in these second-order IIR filters 44b2 to 44b4 are Expressions (2) to (4), respectively.

$$H 2 ( z ) = \frac{b 02 + b 12 {z}^{- 1} + b 22 {z}^{- 2}}{1 + a 12 {z}^{- 1} + a 22 {z}^{- 2}} \qquad ( 2 )$$

$$H 3 ( z ) = \frac{b 03 + b 13 {z}^{- 1} + b 23 {z}^{- 2}}{1 + a 13 {z}^{- 1} + a 23 {z}^{- 2}} \qquad ( 3 )$$

$$H 4 ( z ) = \frac{b 04 + b 14 {z}^{- 1} + b 24 {z}^{- 2}}{1 + a 14 {z}^{- 1} + a 24 {z}^{- 2}} \qquad ( 4 )$$

Simulation may be performed for each of the second-order IIR filters 44b1 to 44b4, or the characteristic obtained by the combination of the second-order IIR filters 44b1 to 44b4 may be simulated. As shown in FIG. 4, the programmable filter 44b including a plurality of second-order IIR filters 44b1 to 44b4 coupled in series functions so as to sequentially perform each digital filtering process. The characteristic of the programmable filter 44b can then be described by a transfer function obtained by multiplying the transfer function of each filter. Therefore, simulation may be performed for each transfer function, or the characteristic of the combination of respective filters may be simulated based on the product of the transfer functions. Since the characteristics obtained by coupling the filters in series can be described by the product of the transfer functions, the processing order of the second-order IIR filters 44b1 to 44b4 may be any order.

Once the filter coefficients are determined by simulation, the user operates an external device and transmits filter setting data indicating the determined filter coefficients to the physical quantity sensor 1. When the filter setting data is transmitted, the interface circuit 70 acquires the filter setting data and stores the filter setting data in the first area of the register 61. Once the filter setting data is stored in the register 61, the programmable filter 44b applies respective filter coefficients to each of the second-order IIR filters 44b1 to 44b4. As a result, the programmable filter 44b functions as a filter with the characteristic desired by the user.

For example, the programmable filter 44b is set to perform any one or a combination of the bandpass filtering process, the notch filtering process, the low-pass filtering process, and the high-pass filtering process. When a21 and b21 among the filter coefficients of the second-order IIR filter 44b1 are set to 0, the second-order IIR filter 44b1 functions as a first-order filter. Thus, the user can make the programmable filter 44b function as a filter of any order from first-order to eighth-order by adjusting the filter coefficients of the second-order IIR filters 44b1 to 44b4.

The selectable filter 44c is a filter that allows the user to select a digital filtering process with a predetermined characteristic. The user selects the desired characteristic from the predetermined characteristics shown in FIG. 2 by referring to the manual and the like. In other words, the user identifies the desired order n and the desired cutoff frequency fc based on the phase delay characteristic, the group delay characteristic, and the like. Once the order n and the cutoff frequency fc are identified, the user operates an external device to transmit the order n and the cutoff frequency fc to the physical quantity sensor 1.

When the order n and the cutoff frequency fc are transmitted, the interface circuit 70 acquires the order n and the cutoff frequency fc, and stores the order n and the cutoff frequency fc in the default area of the register 61. Once the order n and the cutoff frequency fc are stored in the register 61, the selectable filter 44c refers to the nonvolatile memory 62 to transfer the filter coefficient associated with the order n and the cutoff frequency fc to the register 61. The selectable filter 44c then applies the filter coefficient to the selectable filter 44c. As a result, the selectable filter 44c functions as a filter with a characteristic that the user-selects.

The output signals of the programmable filter 44b and the selectable filter 44c are input to the selector 44e. The selector 44e selects and outputs any one of two input signals based on a selection setting value sel1. The selection setting value sel1 is a value determined according to the mode set at the activation of the physical quantity sensor 1, and the like. In the present embodiment, when the selection setting value sel1 is on, the output of the programmable filter 44b is output from the selector 44e. When the selection setting value sel1 is off, the output of the selectable filter 44c is output from the selector 44e. Therefore, in the present embodiment, the digital filtering process of either one of the programmable filter 44b or the selectable filter 44c is applied to the signal output from the sensor element 2. The above configuration allows the user to select a variety of filters according to his/her needs. In other words, when the default characteristics prepared as the selectable filter 44c are acceptable, it is possible to simply select a filter with the default characteristic by designating the order n and the cutoff frequency fc. When the desired characteristic is not present in the selectable filter 44c, a filter with the characteristic desired by the user can be used by designating the filter coefficients in the programmable filter 44b.

The output signal of the selector 44e is input to the selector 44f and the notch filter 44d. The notch filter 44d is a band elimination filter for attenuating a signal at a specific frequency. The filter coefficients to be applied to the notch filter 44d are identified in advance and stored in the nonvolatile memory 62, and are transferred to the register 61 when the physical quantity sensor 1 is activated. The notch filter 44d applies the filter coefficients to the notch filter 44d. As a result, the notch filter 44d functions as a filter that attenuates the component of the detuned frequency that is the difference between the drive frequency fd and the detection frequency fr.

The selector 44f selects and outputs any one of the two input signals based on a selection setting value sel2. The selection setting value sel2 is a value determined according to the mode set at the activation of the physical quantity sensor 1, and the like. In the present embodiment, when the selection setting value sel2 is on, the output of the selector 44e is output from the selector 44f. When the selection setting value sel2 is off, the output of the notch filter 44d is output from the selector 44f. Therefore, in the present embodiment, the selector 44f selects whether the notch filter 44d is applied to the signal output from the selector 44e. Focusing on the case where the output of the selector 44e is the output of the programmable filter 44b, the output from the selector 44f is either the output of the programmable filter 44b or the output when the notch filter 44d is applied to the programmable filter 44b. In the programmable filter 44b, it is possible to select a setting in which the programmable filter 44b does not function substantially, depending on the filter coefficient. Therefore, focusing on the case where the output of the selector 44e is the output of the programmable filter 44b, the selector 44f outputs a signal Da′ obtained by applying at least one of the programmable filter 44b and the notch filter 44d to the signal output from the sensor element 2. The above configuration allows the user to select a variety of filters according to his/her needs.

The digital signal after the digital filtering process is performed by the DSP 44 is output from the DSP 44 as a digital signal Da′ obtained by correcting the digital signal (angular velocity data) indicating the detection result detected by the sensor element 2. The output mode is not limited, and the DSP 44 may output the generated digital signal Da′ to an external device using the interface circuit 70 or may store the generated digital signal Da′ in the storage unit 60. In this case, the digital signal Da′ is output to the external device via the interface circuit 70 in response to a request from the external device at any timing.

### 2. Setting Process

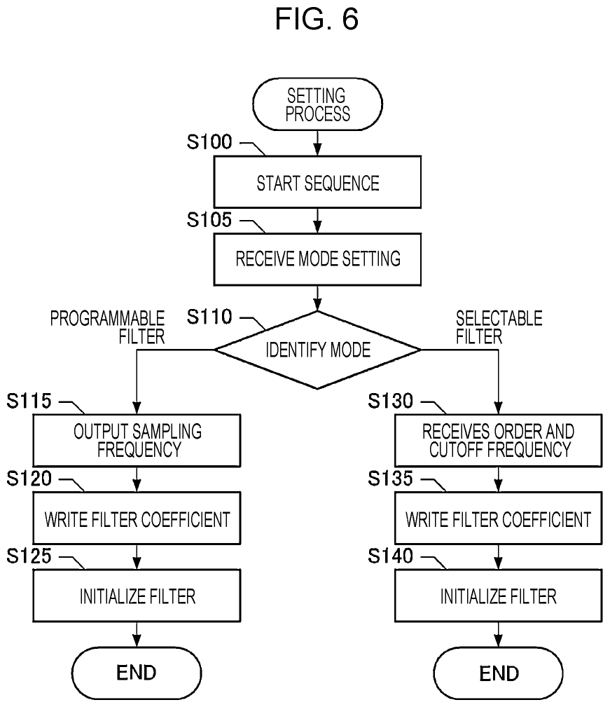

Next, the setting process of causing the desired filter of the DSP 44 of the physical quantity sensor 1 to function is described. FIG. 6 is a flowchart of the process executed after power supply is started from the VDD terminal to the physical quantity sensor 1. Once power is supplied to the physical quantity sensor 1, the DSP 44 performs a predetermined start sequence (step S100). The start sequence may include a variety of processes. In the present embodiment, the start sequence includes the transfer of information from the nonvolatile memory 62 to the register 61. In other words, the DSP 44 reads the sampling frequency fs used by the physical quantity sensor 1 from the nonvolatile memory 62 to store the sampling frequency fs in the first area. The DSP 44 reads the filter coefficients of the notch filter 44d from the nonvolatile memory 62 to store the filter coefficients in the register 61.

The predetermined period after the power supply is started is the reception period for mode setting. During the reception period the user operates the external device to set information indicating the desired mode. The external device transmits information indicating the mode to the physical quantity sensor 1. The interface circuit 70 acquires information indicating the mode and stores the information in a predetermined area of the register 61. When information indicating the mode is stored in a predetermined area of the register 61, the DSP 44 receives mode setting based on the information (step S105).

The information indicating the mode may be defined in any manner, but, in the present embodiment, includes information designating whether the programmable filter 44b or the selectable filter 44c is used. The information indicating the mode in the present embodiment includes information designating whether the notch filter 44d is used.

The DSP 44 identifies the mode set by the user based on the information indicating the mode (step S110). When the mode set by the user is identified in step S110 as a mode that uses the programmable filter 44b, the DSP 44 performs the process of steps S115 to S125. On the other hand, when the mode set by the user is identified in step S110 as a mode that uses the selectable filter 44c, the DSP 44 performs the process of steps S130 to S140.

When the mode set by the user is the mode using the programmable filter 44b, in step S115, the DSP 44 outputs the sampling frequency to an external device. That is, the user operates the external device to read the sampling frequency fs stored in the first area of the register 61.

Next, the DSP 44 writes the filter coefficients to the register 61 (step S120). In other words, the user operates an external device to simulate the characteristic of the programmable filter 44b using the sampling frequency fs to determine the filter coefficients of the second-order IIR filters 44b1 to 44b4. The user then operates the external device to transmit filter setting data indicating the filter coefficients to the physical quantity sensor 1. In the physical quantity sensor 1, the interface circuit 70 receives the filter setting data and stores the filter setting data in the first area of the register 61. In other words, the sampling frequency fs is overwritten by the filter setting data.

Next, the DSP 44 performs a filter initialization (step S125). The filter initialization in step S125 is a process for applying the filter coefficients stored in the first area to the programmable filter 44b. The filter initialization includes a setting process of applying the filter coefficients acquired in step S120 to the second-order IIR filters 44b1 to 44b4 and a process of turning on the selection setting value sel1. When setting to use the notch filter 44d has been made in the information indicating the mode, the process of turning off the selection setting value sel2 is included. When setting to use the notch filter 44d is not made, the process of turning on the selection setting value sel2 is included. When the filter initialization is performed, the DSP 44 sleeps for a predetermined period. After the predetermined period has elapsed, the programmable filter 44b will be in a state to perform a digital filtering process according to the filter coefficient identified by the user.

When the mode set by the user is a mode using the selectable filter 44c, in step S130, the DSP 44 receives the order n and the cutoff frequency fc of the selectable filter 44c. In other words, the user identifies the order n and the cutoff frequency fc to make the filter have the desired characteristic based on the manual and the like. The user then operates an external device to transmit the order n and the cutoff frequency fc to the physical quantity sensor 1. In the physical quantity sensor 1, the interface circuit 70 receives the order n and the cutoff frequency fc and stores the order n and the cutoff frequency fc in the default area of the register 61.

Next, the DSP 44 writes the filter coefficients to the register 61 (step S135). In other words, the DSP 44 refers to the default area of the nonvolatile memory 62 and transfers the filter coefficient associated with the order n and the cutoff frequency fc to the register 61.

Next, the DSP 44 performs a filter initialization (step S140). The filter initialization in step S140 is a process for applying the filter coefficients stored in the register 61 in step S135 to the selectable filter 44c. The filter initialization includes a setting process of applying the filter coefficients acquired in step S135 to the selectable filter 44c and a process of turning off the selection setting value sel1. When setting to use the notch filter 44d has been made in the information indicating the mode, the process of turning off the selection setting value sel2 is included. When setting to use the notch filter 44d is not made, the process of turning on the selection setting value sel2 is included. When the filter initialization is performed, the DSP 44 sleeps for a predetermined period. After the predetermined period has elapsed, the selectable filter 44c will be in a state to perform a digital filtering process according to the filter coefficient identified by the user.

### 3. Other Embodiments, and the Like

The embodiments described above are examples for implementing the present disclosure, and various other embodiments can be used. For example, the processing order of the DSP 44 is not limited to the processing order in the above embodiment, but the processing order may be changed in any order, such as the processing order of the notch filter 44d, the programmable filter 44b. The selectable filter 44c and the notch filter 44d may be omitted when necessary. Of course, another digital filtering process may be added. In addition, the filter coefficients of the notch filter 44d may be user-selectable.

The A/D conversion circuit is only required to A/D convert the signal output from the sensor element. In other words, since an analog signal is output from the sensor element, the A/D conversion circuit is only required to convert the detection value of the physical quantity indicated by the analog signal into a digital signal. The signal input to the A/D conversion circuit may be a signal itself output from the sensor element, or may be a signal obtained by performing various processes on the signal output from the sensor element.

The interface circuit is only required to receive filter setting data that determines the characteristic of each of the plurality of digital filtering processes. In other words, the characteristic of each of the plurality of digital filtering processes is only required to be configurable by filter setting data transmitted from an external device. Filter setting data may be set for all or some of the plurality of digital filters. In the latter case, the default filter setting data is applied to digital filters that have not been set, for example.

The filter setting data is only required to be data that defines the characteristic of the digital filtering process. Therefore, the configuration of adjusting the characteristic of the second-order IIR filter described above using five filter coefficients as filter setting data is an example. For example, IIR filters of any order may be coupled in series, and the characteristic may be specified with filter setting data according to the mode of the filter. The mode of the filter is also not limited, and may be an IIR filter of a mode different from that of the above example, or another filter such as an FIR filter may be used.

Furthermore, in the expression “a plurality of digital filtering processes”, when counting the digital filtering processes, any given processing unit may be counted as one. In the above embodiment, the second-order IIR filter is counted as one digital filtering process, but the present disclosure is not limited to this configuration. For example, one order of the digital filtering processes of n orders may be counted as one digital filtering process.

The storage circuit is only required to store filter setting data. In other words, it is sufficient to the store filter setting data transmitted from an external device and retain the filter setting data for reference in the signal processing circuit. Of course, the storage circuit may store another piece of data.

The signal processing circuit is only required to sequentially perform each of a plurality of digital filtering processes with characteristics determined by the filter setting data on the digital signal output from the A/D conversion circuit. In other words, a plurality of digital filtering processes is only required to be coupled in series and the digital filtering processes is only required to be sequentially executed. Such a configuration is equivalent to performing a digital filtering process of the transfer function obtained by multiplying the transfer function of each of the plurality of digital filtering processes. Of course, the order of execution of respective digital filtering processes is any order. When there is a digital filtering process that has been disabled by the filter setting data, the digital filtering process may not be substantially executed.

The above mentioned embodiments are an example and are not limited to thereto. The present disclosure includes a configuration substantially same as the configuration described in the embodiments (for example, a configuration having the same function, method, and result, or a configuration having the same object and effect). Further, the present disclosure includes a configuration in which a non-essential part of the configuration described in the embodiments is replaced. Further, the present disclosure includes a configuration having the same functions and effects as the configuration described in the embodiments or a configuration capable of achieving the same object. The present disclosure also includes a configuration in which a known technique is added to the configuration described in the embodiments.

What is claimed is:

1. A circuit device comprising:
an A/D conversion circuit that A/D converts a signal output from a sensor element;
an interface circuit that receives filter setting data that determines a characteristic of each of a plurality of digital filtering processes;
a storage circuit that stores the filter setting data; and
a signal processing circuit that sequentially performs each of the plurality of digital filtering processes with characteristics determined by the filter setting data on a digital signal output from the A/D conversion circuit.

2. The circuit device according to claim 1, wherein
the signal processing circuit performs a bandpass filtering process as the digital filtering process.

3. The circuit device according to claim 1, wherein
the signal processing circuit performs a notch filtering process as the digital filtering process.

4. The circuit device according to claim 1, wherein
the signal processing circuit performs a low-pass filtering process as the digital filtering process.

5. The circuit device according to claim 1, wherein
the signal processing circuit performs a high-pass filtering process as the digital filtering process.

6. The circuit device according to claim 1, further comprising:
a drive circuit that vibrates the sensor element at a drive frequency by a drive signal; and
a detection circuit that acquires a signal of a detection frequency from the sensor element, wherein
the signal processing circuit performs at least one of a notch filtering process of attenuating a component of a detuned frequency that is a difference between the drive frequency and the detection frequency, and the plurality of digital filtering processes.

7. The circuit device according to claim 1, wherein
the storage circuit further stores information for setting a low-pass filtering process for an order and a cutoff frequency that are designated by a user, and wherein
the signal processing circuit performs one of the low-pass filtering process of the order and the cutoff frequency corresponding to the information and the plurality of digital filtering processes.

8. The circuit device according to claim 1, wherein
in an initial state, the storage circuit stores individual data corresponding to a sampling frequency of the A/D conversion circuit in a first area, and wherein
the first area is overwritten by the filter setting data input from the interface circuit.

9. A method of setting a circuit device including an A/D conversion circuit that A/D converts a signal output from a sensor element, an interface circuit, a storage circuit, and a signal processing circuit that performs a digital filtering process on a digital signal output from the A/D conversion circuit, the method comprising:
inputting filter setting data that determines a characteristic of each of a plurality of digital filtering processes into the interface circuit, and storing the filter setting data in the storage circuit; and
causing the signal processing circuit to sequentially perform each of the plurality of digital filtering processes with characteristics determined by the filter setting data on the digital signal output from the A/D conversion circuit.
